(19) United States
(12) Patent Application Publication
(10) Pub. No.: US 2024/0373578 A1
(43) Pub. Date: Nov. 7, 2024

(54) POWER MODULE AND METHOD FOR MANUFACTURING A POWER MODULE

(71) Applicant: Danfoss Silicon Power GmbH, Flensburg (DE)

(72) Inventors: Fabio CARASTRO, Munich (DE); Thomas ZOELS, Hebertshausen (DE)

(21) Appl. No.: 18/654,313

(22) Filed: May 3, 2024

(30) Foreign Application Priority Data
May 5, 2023 (DE) 102023111745.9

(51) Int. Cl. H05K 7/14

(52) U.S. Cl. CPC H05K 7/14322; H05K 7/14329; H05K 7/14339

(57) ABSTRACT

The disclosure relates to a power module including a semiconductor power circuit, a conductor and a first core part being arranged besides the conductor such that it can form a core together with a second core part. The disclosure further relates to methods for manufacturing such a power module.

### CROSS-REFERENCE TO RELATED APPLICATIONS

This application claims foreign priority benefits under 35 U.S.C. § 119 from German Patent Application No. 102023111745.9, filed May 5, 2023, the content of which is hereby incorporated by reference in its entirety.

### TECHNICAL FIELD

The invention relates to a power module with a semiconductor power circuit and to corresponding methods of manufacturing a power module.

### BACKGROUND

Power modules are used, for example, in order to provide or amplify a power that can be used for driving an electric motor or an electric heater. Typically, such power modules comprise a power circuit, especially a semiconductor power circuit, and at least one conductor for conducting current to and/or from the power circuit. It is typically preferable to have information about the current flowing through the conductor, which may be implemented by using an integrated current sensor.

### SUMMARY

It is thus an object of the invention to provide a power module in which the current sensor can be manufactured in an easy way. It is a further object of the invention to provide corresponding methods. This is achieved by a power module and by methods according to the respective main claims. Preferred embodiments are claimed in the dependent claims.

The invention relates to a power module. The power module comprises a semiconductor power circuit. The power module further comprises a conductor for conducting a primary current to and/or from the power circuit. The conductor has a first side and a second side opposite to the first side. The power module comprises a first core part being arranged at the first side of the conductor such that if a second core part is placed at the second side of the conductor, the first core part and the second core part together form a core at least essentially surrounding the conductor.

With such a power module, it is specifically easy to fabricate a power module with an integrated current sensor, because a first core part of a core, that can be used in order to form a current sensor, is already part of the power module. The integrated first core part is also a space-saving implementation that can be placed in the vicinity or even in direct contact with the conductor.

The power circuit may especially be a semiconductor power circuit. It may especially be used in order to switch a current, which may be delivered to an external entity by using the conductor. The conductor may also be used in order to deliver a current to the power circuit. In a specific implementation, the power module may have two conductors, wherein each conductor may have a corresponding first core part as disclosed herein. It is also possible to use more than two conductors accordingly. All statements are applicable for such cases.

The conductor may especially have a flat shape and/or a bulk shape. Especially, it is not embodied as a coil. A cross section seen transverse to a current flow direction may especially be rectangular. The current flow path may be straight. The cross section of the conductor may especially be constant or at least approximately constant along the current flow path or along a straight line.

The first core part is adapted to cooperate with a second core part, which is not yet part of the power module in the broadest scope. The second core part and the first core part together form a core, which has the typical properties of a magnetic core. Especially, such a core may direct a magnetic field to a Hall sensor, so that the Hall sensor can detect the magnetic field. The core can especially be used to increase the sensitivity compared with using a Hall sensor alone.

The first core part may comprise a first interface surface and a second interface surface, the first interface surface and the second interface surface especially being suitable for being positioned in close proximity to the corresponding interface surfaces of the second core part. Such interface surfaces may also form surfaces of gaps between the first core part and the second core part in a final state. Especially, the first interface surface and the second interface surface may be coplanar.

It may especially be provided that the core, at least in the final state, completely surrounds the conductor.

According to an implementation, the first core part has a U-shape in cross-section. This may allow for an easy implementation and an easy adaptation to a flat conductor.

Especially, the first core part may have, in cross-section, a first short section, a second short section and a long section. The first short section and the second short section may both be shorter than the long section. The first short section may be attached to the long section and may provide a first surface facing towards the second core part. The second short section may be attached to the long section and may provide a second surface facing towards the second core part. With such an implementation, the first core part may fit between a bottom section and the conductor in the power module. The short sections may face towards the second core part in a final state. In an implementation, the sections may each be straight. In an implementation, there may be no further sections than the mentioned sections. Especially, the first core part may not be a coil. Similar considerations may apply for the second core part.

Especially, the conductor may have a first notch and a second notch. The first core part may protrude through the first notch and through the second notch. Such notches may especially be provided at opposing sides of the conductor. Especially, they may be provided such that the notches open towards the outside of the conductor. In other words, the conductor may be smaller for a limited part of its length, so that the first core part may fully or at least partially or substantially fit in the extent of the conductor defined by the other parts of the conductor and does not lead to an additional required space besides the conductor.

If an implementation of the first core part as described above with short sections and a long section is used, it can especially be provided that the first short section of the first core part protrudes through the first notch and the second short section of the first core part protrudes through the second notch.

Especially, the first notch and the second notch may be arranged in opposite transverse sides of the conductor. This may save space of the conductor in the specific orientation.

The notches may especially abut the first core part and define its position in one or two directions. Especially they may define its position in two directions being parallel to the extension of the conductor. It may also be stated that the notches define the position of the first core part in a plane defined by the extension of the conductor. This allows for using the notches not only to save space, but also to define the position of the first core part or at least a part of the positioning, so that a defined position relationship between the first core part and other components, especially the second core part, is achieved which can, for example, omit the necessity to calibrate each sensor after fabricating.

In an implementation, it may be provided that the conductor has, at least adjacent to the first core part, a constant width. This can be regarded as an alternative implementation to using the notches described above. With a conductor having a constant width, the first core part can especially be arranged besides the conductor and may extend the total space requirement in a direction transverse to the longest extension of the conductor. With such an implementation, a narrowing of the conductor can be omitted, which can, for example, be used in order to omit an increase in resistance.

According to an implementation, the first core part may be permanently fixed within the power module. This may allow for a secure implementation and a fixed position relationship.

Especially, the first core part may be molded within a mold material and/or a gel and/or may be potted in the power module. Such manufacturing methods may especially be used in order to fix the first core part in the power module. For example, the first core part can be placed half inside, half outside of a material like a mold material and/or a gel so that a part of the first core part is securely fixed, but parts needed for providing functionality like forming a core are easily accessible.

Especially, the semiconductor power circuit may be molded within a mold material and/or a gel and/or may be potted in the power module. This integrates the semiconductor power circuit with a tight packaging into the power module.

Preferably, the first core part and the semiconductor power circuit may be molded within the same portion of mold material. Thus, only one mold material and one corresponding step of applying the mold material are required, which simplifies production. The mold material secures both entities against mechanical or electrical hazards. Especially, the same portion of mold material can contact both entities directly.

Especially, the semiconductor power circuit may be molded completely around, or may at least cover a side facing away from a base. Especially, the first core part may be molded partially around, especially such that interface surfaces protrude from the molding.

The semiconductor power circuit may comprise at least one means for switching current in a controlled manner. Especially, high currents of at least several amperes may be switched. The means for switching current may especially comprise one or more MOSFETs (Metal Oxide Semiconductor Field Effect Transistors) and/or IGBTs (Insulated Gate Bipolar Transistors). However, also other switching technologies may be used in addition or alternatively.

A current that is switched by the means for switching current may especially be conducted by the conductor. There it can preferably be measured using a current sensor to which the first core part belongs.

Especially, the first core part may have one or more protrusions. The conductor may especially have one or more recesses. It may especially be provided, that each protrusion engages in one recess such that it is closely engaged in the recess so as to define the position and/or orientation of the first core part relative to the conductor. With such a combination of protrusions and recesses, the positional relationship between the first core part and the conductor may be defined in an easy and reliable way. It is also possible to use a different implementation, i.e., the conductor has the protrusions and the first core part has the recesses.

The protrusions may have a cylindrical form. The recesses may have a hollow cylindrical form. Instead of a cylindrical cross section of a cylinder, also other shapes like squares can be used.

According to an implementation, the first side of the conductor may be a flat side. According to an implementation, the second side of the conductor may be a flat side. Especially, a flat side may provide a flat surface and may thus fit to a flat or at least substantially flat counterpart of a core part without loss of room. A flat side may be extending in a plane without interruption. It is especially different from a surface of a coil and from a conductor having a round cross section. A flat side may have a rectangular or at least approximately rectangular shape.

Especially, the power module may further comprise a second core part being arranged at the second side of the conductor such that the first core part and the second core part together form a core surrounding the conductor. This may complete a core in order to provide for a concentration of magnetic field lines generated by a current flowing through the conductor at a suitable place, especially at a magnetic sensor like a Hall sensor as discussed below.

The core may have a first clearance being arranged between the first core part and the second core part. The core may have a second clearance being arranged between the first core part and the second part, the second clearance being different from the first clearance. This may allow for a suitable clearance between the core parts so that magnetization of the core can be adjusted. For example, the clearances can be used in order to adjust a saturation magnetization according to expected currents flowing in the conductor.

The second core part may be embodied mirror-invertedly to the first core part. This allows, for example, for using the same kind of parts for the first core part and the second core part.

The power module may further comprise a magnetic sensor being arranged between the first core part and the second core part, the core and the magnetic sensor together forming a current sensor for measuring a current flowing in the conductor. The core may concentrate magnetic field lines at the position of the magnetic sensor. This allows for increased sensibility compared to using a magnetic sensor without a core. Especially, the magnetic sensor may be a Hall sensor.

The second core part and/or the magnetic sensor may be arranged in one housing. This allows for handling the second core part and the magnetic sensor together by handling the housing. The housing may be placed in a suitable position in order to form the final power module.

The housing may especially be secured to the rest of the power module by click-fixing. This allows an easy securing of the housing to the rest of the power module. However, also other methods of fixing the housing may be used.

The power module may further comprise an evaluation device operatively connected with the magnetic sensor and being arranged in the housing. It may further comprise at least one electrical sensor connection passing through the housing and/or extending from the housing. Thus, the housing may comprise further functionality, especially an evaluation device. This may further simplify fabrication.

The housing may have an open side being covered by a circuit board, or by a gate driver circuit board. The open side of the housing may especially be open when the circuit board is not present. After putting the circuit board in a suitable place, the circuit board may also provide for covering and/or closing the opening.

Especially, the core may be made of a ferro-magnetic material. This may especially be true for the first core part and the second core part, or for only one of these parts.

The invention further relates to a method of manufacturing a power module, the method comprising the following steps:
providing a first core part,
providing a power module base,
fixing the first core part to the power module base, and then
fixing the conductor to the power module base such that the first core part is arranged at a first side of the conductor.

This may allow for an easy manufacturing of a power module, especially in a state before applying a second core part.

The invention relates further to a method of manufacturing a power module, the method comprising the following steps:
providing a first core part,
providing a power module base,
fixing the first core part to the conductor such that the first core part is arranged at a first side of the conductor, and then
fixing the conductor to the power module base.

Also this may allow for easy fabrication of a power module in a state before attaching the second core part.

Especially, the method may further comprise a step of molding and/or potting the first core part in the power module base. For example, a suitable mold material and/or a gel may be used for this purpose. With this step, also the semiconductor power circuit can be molded and/or potted.

The power module may especially be manufactured as described above, especially to have a state and/or having features as described above. All disclosed variants can be applied.

The invention relates further to a method of manufacturing a power module, the method comprising the following steps:
providing a power module as disclosed herein and/or manufactured according to a method as disclosed herein, not yet having a second core part,
providing a second core part,
fixing the second core part on the power module such that the first core part and the second core part together form a core.

With such a method, a power module having two core parts forming a core can easily be manufactured. Especially, a power module with a second core part as described above can be manufactured. This may especially relate to the end state of the method. All disclosed variants can be applied.

Especially, the second core part may be provided in a housing. The housing may further encompass an evaluation module and/or a magnetic sensor.

The housing may have an open side, and the method may further comprise a step of mounting a circuit board, or a gate driver circuit board, covering the open side.

The method may further comprise a step of molding the power module with a mold material and/or a gel. This may allow for achieving a permanent end state of the method with the components being fixed by using the hardened mold material and/or gel.

The conductor may especially be provided as part of a lead frame. The outer parts of the lead frame may be removed after the step of molding. Especially, a lead frame may be a frame made of a conducting material having pins or other connection elements like the conductor as described herein and may further have surrounding elements holding the conducting elements in place until they are held in place by other means, especially by molding or other fixation techniques. Afterwards, the surrounding elements can be removed, and the conductor will be held in place by other elements of the power module.

Especially, the sensor may be an open-loop current sensor, which may especially use the Hall-effect principle to measure the flux density induced by the current through the sensor. The sensor may comprise a magnetic core which encircles the current carrying conductor. A small gap in this core may be used by the sensor as a measurement point. The sensor may have a magnetic core which is split into two separate sections. They may be brought together in the final sensor to form a magnetic core with two gaps. The bottom magnetic core may be fixed within the power module itself. The top magnetic core may be housed in a separate body, especially together with the measurement and signal processing and connections to the outside equipment, wherein the body may be brought into position and held in position by, for example, a click fixing after the production of the power module itself. The first core part may especially be half molded into the body of the module.

The concept disclosed herein especially provides for a magnetic core design that is small enough to fit in a limited space which would otherwise be unused. Especially, the magnetic core may surround a bus bar or a conductor with a dual air gap and a small reluctance path to reduce the flux density in the magnetic core and to push away the core saturation at higher currents. Two straight ferro-magnetic bars may be used, one placed underneath a conductor and one placed on top of it, especially with a Hall-plate sensing element located in one or two of the air gaps.

### BRIEF DESCRIPTION OF THE DRAWINGS

The invention will now be described with reference to the drawings, wherein

FIG. 1: shows a conductor and a core according to a first embodiment,

FIG. 2: shows a conductor and a core according to a second embodiment,

FIG. 3: shows some of the same parts of FIG. 1 in a different view,

FIG. 4: shows some of the parts of FIG. 2 in a different view,

FIG. 5: shows a core and a magnetic sensor according to a third embodiment,

FIG. 6: shows a core and a magnetic sensor according to a fourth embodiment,

FIG. 7 shows a conductor and a core according to the third embodiment,

FIG. 8 shows a conductor and a core according to the fourth embodiment,

FIG. 9 shows a power module in an exploded view,

FIG. 10 shows the power module in a finally assembled state, and

FIG. 11 shows a sectional view of the power module.

### DETAILED DESCRIPTION

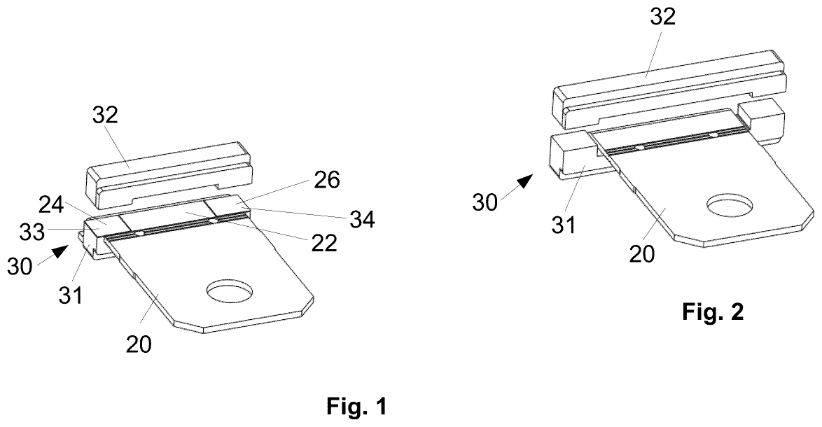

FIG. 1 shows a conductor 20 and a core 30 according to a first embodiment. The conductor 20 is embodied as a flat connector that can be used for a power module as will be shown further below. The core 30 is divided into a first core part 31 and a second core part 32. The first core part 31 has a U-shape and is positioned below the conductor 20, at a lower side of the conductor 20 that may be denoted as a first side. The second core part 32 also has a U-shape and is positioned above the conductor 20, at an upper side of the conductor 20 that may be denoted as a second side. The conductor 20 has a first notch 24 and a second notch 26, between which a narrow part 22 of the conductor 20 is positioned. As shown, parts of the first core part 31 protrude through the notches 24, 26. The second core part 32 is positioned such that the two core parts 31, 32 together form a core 30 comprising the two core parts 31, 32 and having clearances between these core parts 31, 32. Using the notches 24, 26, an extension of space required by an assembled current sensor in a direction perpendicular to the longitudinal extension of the conductor 20 can be limited.

The first core part 31 has a first interface surface 33 and a second interface surface 34 facing towards the second core part 32. These interface surfaces 33, 34 are coplanar to each other and are furthermore coplanar to the upper surface of the conductor 20.

FIG. 2 also shows a conductor 20 and a core 30, but according to a second embodiment. In the second embodiment, the conductor 20 does not have notches, but has a constant width and the first part 31 of the core 30 is positioned besides the conductor 20. Thus, a narrowing of the conductor 20 can be omitted, thus increasing the current-carrying capacity of the conductor 20 over that of the first embodiment.

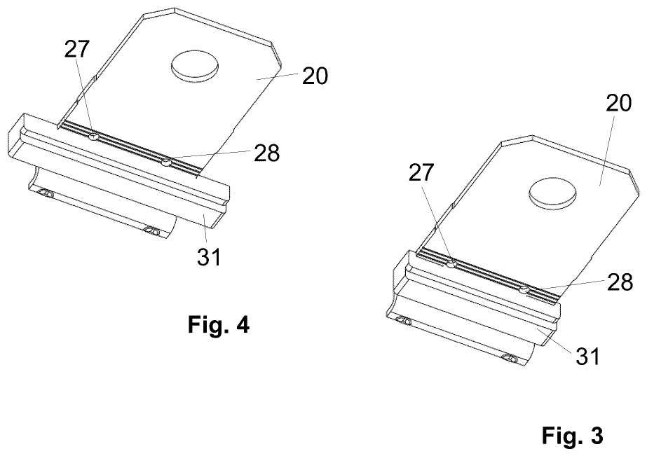

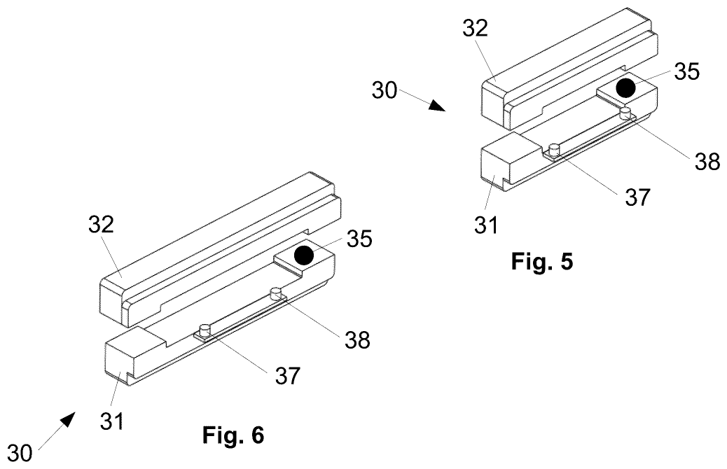

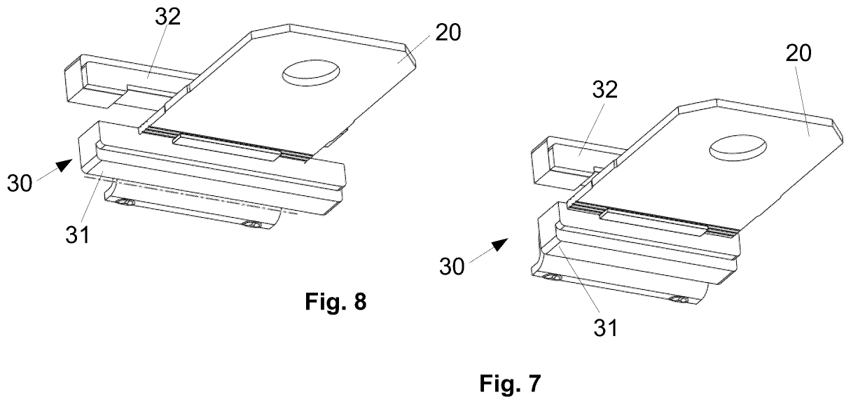

FIG. 3 shows the conductor 20 and the first core part 31 of the first embodiment in a view from below. There it can be seen that immediately besides the first core part 31 the conductor 20 has a first recess 27 and a second recess 28. These recesses 27, 28 do not have a function in the embodiment shown in FIG. 3, but will have a function a third embodiment shown further below in FIGS. 5 and 7.

FIG. 4 shows a corresponding view for the second embodiment with the first core part being wider and the conductor 20 not having notches, but also having the two recesses 27, 28.

FIG. 5 shows a core 30 according to a third embodiment, being a variation of the first embodiment, together with a magnetic sensor 35. The magnetic sensor 35 is a Hall sensor and is positioned in a clearance between the first core part 31 and the second core part 32. If the conductor 20, which is not shown in FIG. 5, protrudes through the core 30, a current flowing through the conductor will induce a magnetic field, which will be confined by the core 30 so as to have a high magnetic field strength at the position of the magnetic sensor 35. Thus, the magnetic sensor 35 can measure the magnetic field, and thus the current, with a high sensitivity. The clearances between the two core parts 31, 32 can be used in order to adapt the saturation magnetization.

In contrast to the first embodiment shown in FIGS. 1 and 3, the third embodiment shown in FIG. 5 shows the first core part 31 having a first protrusion 37 and a second protrusion 38. The two protrusions 37, 38 may engage in the recesses 27, 28 of the conductor 20 shown in FIG. 3. In an assembled state, this leads to a situation as shown in FIG. 7. The recesses 27, 28 thus define the position of the two protrusions 37, 38 of the first core part 31 and thus define the position of the first core part 31 in two directions which are defined by the extension of the main part of the conductor 20. This allows for using the recesses 27, 28 of the conductor 20 for defining the lateral position of the first core part 31. FIGS. 6 and 8 show the corresponding parts for a fourth embodiment with a wider core and a conductor not having notches, being a variation of the second embodiment.

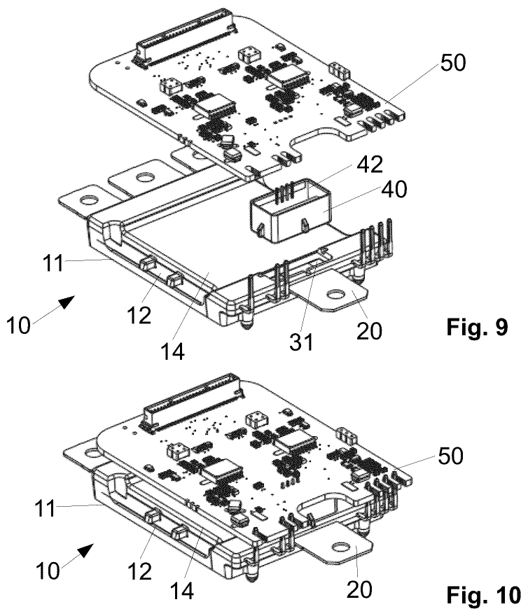

FIG. 9 shows a power module 10 in an exploded view. The power module 10 comprises a semiconductor power circuit 12, which is encapsulated in a molded body 14 of a power module base 11. The semiconductor power circuit 12 comprises switching means like MOSFETs and/or IGBTs in order to switch a current flowing through the conductor 20. The molded body 14 comprises a mold material which protects the semiconductor power circuit 12 and other internal components of the power module base 11 from environmental dust or chemicals. In addition, the conductor 20 and first core part 31 are embedded in the molded body 14 and are thus held rigidly in their relative positions.

The conductor 20, which has already been discussed with reference to FIGS. 1 to 8, is part of the power module 10 and protrudes from the semiconductor power circuit 12. It may conduct a current to or from the semiconductor power circuit 12. A first core part 31 is also visible in FIG. 9, because it is an exploded view.

Immediately above the first core part 31 is positioned a housing 40. The housing 40 houses a second core part as discussed with reference to FIGS. 1 to 8, but which is not visible in FIG. 9. The housing 40 has an opening 42 facing upwards. The power module 10 further comprises a gate driver circuit board 50, which covers the power module 10 and also covers and closes the opening 42 in an assembled state.

The assembled state is shown in FIG. 10. There it can be seen that the power module 10 is a compact arrangement primarily enclosed by the power module base 11 and the gate driver circuit board 50. The conductor 20 protrudes from the rest of the power module 10.

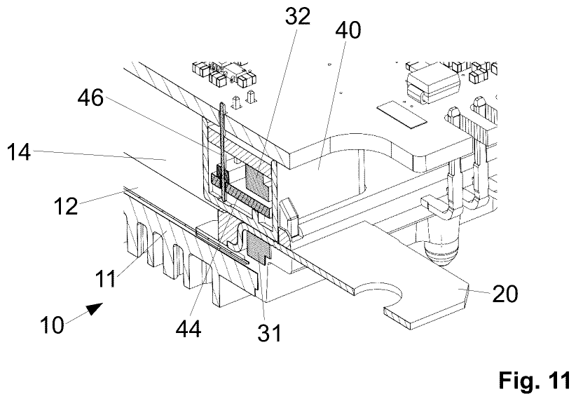

FIG. 11 shows the power module 10 in a sectional view. There it can be seen that the housing 40 encompasses the second core part 32 and encompasses furthermore an evaluation device 44. The evaluation device 44 is adapted in order to read out the magnetic sensor already discussed above and to deliver a signal corresponding to the current flowing in the conductor 20. The housing 40 further comprises a connecting pin, forming a sensor connection 46 which is connected to the gate driver circuit board 50. Thus, the housing 40 is a compact module that can be used for fabricating the power module 10, wherein the housing 40 comprises at least the second core part 32, the evaluation device 44 and the sensor connection 46 as one component which may be fixed to the other parts of the power module 10 in just one step.

As shown in FIG. 11, the first core part 31 directly connects to the conductor 20 in the shown embodiment. It is possible to place an electrical isolation layer between the conductor 20 and the first core part 31. However, alternatively a contact between these two parts is possible and does not lead to any detrimental effect, as long as the first core part 31 is not connected with any further electrically conducting element.

It should be noted that all embodiments as discussed with reference to FIGS. 1 to 8 of the conductor 20 and the core 30 may be used in the power module shown in FIGS. 9 to 11.

While the present disclosure has been illustrated and described with respect to a particular embodiment thereof, it should be appreciated by those of ordinary skill in the art that various modifications to this disclosure may be made without departing from the spirit and scope of the present disclosure.

1. A power module, comprising
a semiconductor power circuit,
a conductor for conducting a primary current to and/or from the semiconductor power circuit, the conductor having a first side and a second side opposite to the first side,
a first core part being arranged at the first side of the conductor such that if a second core part is placed at the second side of the conductor, the first core part and the second core part together form a core at least essentially surrounding the conductor.

2. The power module according to claim 1,
wherein the first core part comprises a first interface surface and a second interface surface, the first interface surface and the second interface surface being suitable for being positioned in close proximity of corresponding interface surfaces of the second core part.

3. The power module according to claim 2,
wherein the first interface surface and the second interface surface are coplanar.

4. The power module according to claim 1,
wherein the first core part has a U-shape in cross section.

5. The power module according to claim 1,
wherein the conductor has a first notch and a second notch, wherein the first core part protrudes through the first notch and through the second notch.

6. The power module according to claim 5,
wherein the first notch and the second notch are arranged at opposite trans-verse sides of the conductor.

7. The power module according to claim 5,
wherein the notches abut the first core part and define its position in one or two directions.

8. The power module according to claim 1,
wherein the conductor has, at least adjacent to the first core part, a constant width.

9. The power module according to claim 1,
wherein the first core part is permanently fixed within the power module.

10. The power module according to claim 1,
wherein the first core part is molded within a mold material and/or a gel and/or is pot-ted in the power module.

11. The power module according to claim 1,
wherein the semiconductor power circuit is molded within a mold material and/or a gel and/or is potted in the power module.

12. The power module according to claim 1,
wherein the first core part and the semiconductor power circuit are molded with-in the same portion of mold material.

13. The power module according to claim 1,
wherein the semiconductor power circuit comprises at least one means for switching current in a controlled manner.

14. The power module according to claim 13,
wherein the means for switching current comprises one or more MOSFETs and/or IGBTs.

15. The power module according to claim 13,
wherein a current switched by the means for switching current is conducted by the conductor.

16. The power module according to claim 1,
wherein the first core part has one or more protrusions,
wherein the conductor has one or more recesses, and
wherein each protrusion engages in one recess such that it is closely engaged in the recess so as to define the position and/or orientation of the first core part relative to the conductor; and/or
wherein the conductor has one or more protrusions,
wherein the first core part has one or more recesses, and
wherein each protrusion engages in one recess such that it is closely engaged in the recess so as to define the position and/or orientation of the first core part relative to the conductor.

17. The power module according to claim 1,
wherein the first side of the conductor is a flat side, and/or
wherein the second side of the conductor is a flat side.

18. The power module according to claim 1,
further comprising a second core part being arranged at the second side of the conductor such that the first core part and the second core part together form a core surrounding the conductor.

19. The power module according to claim 18,
wherein the core has a first clearance being arranged between the first core part and the second core part.

20. The power module according to claim 19,
wherein the core has a second clearance being arranged between the first core part and the second core part, the second clearance being different from the first clearance.

21. The power module according to claim 18,
wherein the second core part is embodied mirror invertedly to the first core part.

22. The power module according to claim 18,
further comprising a magnetic sensor being arranged between the first core part and the second core part, the core and the magnetic sensor together forming a current sensor for measuring a current flowing in the conductor.

23. The power module according to claim 22,
wherein the magnetic sensor is a Hall sensor.

24. The power module according to claim 18,
wherein the second core part and/or the magnetic sensor are arranged in one housing.

25. The power module according to claim 24,
wherein the housing is secured to the rest of the power module by click fixing.

26. The power module according to claim 24,
further comprising an evaluation device operatively connected with the magnetic sensor and being arranged in the housing, and/or
further comprising at least one electrical sensor connection passing through the housing and/or extending from the housing.

27. A method of manufacturing a power module, the method comprising the following steps:
providing a first core part,
providing a power module base,
fixing the first core part to the power module base, and then
fixing the conductor to the power module base such that the first core part is arranged at a first side of the conductor.

28. A method of manufacturing a power module, the method comprising the following steps:
providing a first core part,
providing a power module base,
fixing the first core part to the conductor such that the first core part is arranged at a first side of the conductor, and then
fixing the conductor to the power module base.

29. The method according to claim 27,
further comprising a step of molding and/or potting the first core part in the power module base.

30. The method according to claim 27,
wherein a power module is manufactured, wherein the power module comprises:
a semiconductor power circuit,
a conductor for conducting a primary current to and/or from the semiconductor power circuit, the conductor having a first side and a second side opposite to the first side,
a first core part being arranged at the first side of the conductor such that if a second core part is placed at the second side of the conductor, the first core part and the second core part together form a core at least essentially surrounding the conductor.

31. A method of manufacturing a power module, the method comprising the following steps:
providing a power module wherein the power module comprises:
a semiconductor power circuit,
a conductor for conducting a primary current to and/or from the semiconductor power circuit, the conductor having a first side and a second side opposite to the first side,
a first core part being arranged at the first side of the conductor such that if a second core part is placed at the second side of the conductor, the first core part and the second core part together form a core at least essentially surrounding the conductor;
and/or manufactured according to claim 27, not yet having a second core part,
providing a second core part,
fixing the second core part on the power module such that the first core part and the second core part together form a core.

32. The method according to claim 31,
wherein the power module is manufactured, such that the power module further comprises:
a second core part being arranged at the second side of the conductor such that the first core part and the second core part together form a core surrounding the conductor.

33. The method according to claim 31,
wherein the second core part is provided in a housing, the housing further encompassing an evaluation device and/or a magnetic sensor.

34. The method according to claim 31, further comprising a step of
molding the power module with a mold material and/or a gel.

35. The method according to claim 34,.
wherein the conductor is provided as part of a lead frame, and.
wherein outer parts of the lead frame are removed after the step of molding.
